(19) United States
(12) Patent Application Publication
(10) Pub. No.: US 2018/0062636 A1
(43) Pub. Date: Mar. 1, 2018

(54) Floating Gate Switch

(71) Applicant: Qualcomm Incorporated, San DIego, CA (US)

(72) Inventors: Hayg-Taniel Dabag, San Diego, CA (US); Bhushan Shanti Asuri, San Diego, CA (US); Hongyan Yan, San Diego, CA (US); Sy-Chyuan Hwu, San Diego, CA (US); Youngchang Yoon, Seoul (KR)

(21) Appl. No.: 15/634,800

(22) Filed: Jun. 27, 2017

Related U.S. Application Data
(60) Provisional application No. 62/380,197, filed on Aug. 26, 2016.

(51) Int. Cl. H03K 17/16

(52) U.S. Cl. CPC H03K 17/161

(57) ABSTRACT

Various aspects of this disclosure describe configuring and operating a transistor switch. Examples include a self-biasing circuit that contains a diode-connected transistor whose source or drain is connected to the gate of a transistor configured as a switch. The diode-connected transistor is enabled and disabled responsive to voltage swings in the input signal to the transistor configured as a switch. When enabled, the diode-connected transistor may charge the floating gate voltage of the transistor configured as a switch. When disabled, the diode-connected transistor may acts as a high impedance to inhibit voltage discharge from the gate of the transistor configured as a switch.

### CLAIM OF PRIORITY UNDER 35 U.S.C. § 119

The present application claims the benefit of U.S. Provisional Application Ser. No. 62/380,197, entitled “FLOATING GATE SWITCH” and filed Aug. 26, 2016, which is assigned to the assignee of the present application and expressly incorporated by reference herein in its entirety.

### BACKGROUND

### Field of the Disclosure

The present disclosure relates to a transistor switch.

### Description of Related Art

Switches are used throughout computing devices, such as for separating transmitting and receiving signals that may share an antenna in a cellular phone, as building blocks to construct multiplexors, and generally to route data appropriately within the computing device. Switches can be implemented using transistors or logic gates. Transistor switches with a fixed voltage on the gate of the transistor suffer degradations in performance, including linearity and insertion loss, when the input voltage swing is high. For example, when the switch is in an on state (e.g., the switch is “closed” or enabled), large voltage swings in the input signal cause an increase in non-linear distortion terms measured on the output signal of the switch, such as third-order intercept points.

A charge pump circuit is sometimes used to drive the gate of a transistor configured as a switch, or a resistor is used to float the gate voltage of the transistor, in attempts to maintain acceptable switch linearity performance. Charge pump circuits, however, may be expensive, in terms of area, power, and complexity. Furthermore, charge pump circuits may require a clock signal to operate. A resistor, on the other hand, may be simply operated in some implementations. However, the size of the resistor (e.g., the required resistance value of the resistor) scales inversely proportionally to the operating frequency of the input signal to the switch. Hence, what might be implementable for a switch processing radio frequency (RF) signals may be prohibitive for a switch in a baseband environment due to the required size of the resistor.

### SUMMARY

This Summary is provided to introduce a selection of concepts in a simplified form that are further described below in the Detailed Description. This Summary is not intended to identify key features or essential features of the claimed subject matter.

In some aspects, a switch comprises a first transistor and a second transistor. The first transistor has a source connected to an input of the switch and a drain connected to an output of the switch. The input of the switch is configured to receive an input signal. The second transistor is connected as a diode and has a source or drain connected to a gate of the first transistor.

In other aspects, a method of operating a switch comprises applying an input signal to a source of a first transistor. A first voltage is applied to a gate and a drain of a second transistor that is connected as a diode. A gate of the first transistor is charged to a second voltage using a source of the second transistor. The second voltage on the gate of the first transistor is changed to a third voltage responsive to a change in voltage of the input signal. On and off states of the second transistor are controlled based on the third voltage. The input signal is transferred to a drain of the first transistor.

In still other aspects, a method of operating a switch comprises applying an input signal to a source of a first transistor. A first voltage is applied to a source of a second transistor. A gate and drain of the second transistor may be connected. A gate of the first transistor is charged to a second voltage using the drain of the second transistor. The second voltage on the gate of the first transistor is changed to a third voltage responsive to a change in voltage of the input signal. On and off states of the second transistor are controlled based on the third voltage. The input signal is transferred to a drain of the first transistor.

In yet other aspects, a device comprises means for applying an input signal to a source of a first transistor. The device also comprises means for applying a first voltage to a gate and a drain of a second transistor that is connected as a diode. The device also comprises means for floating a voltage of a gate of the first transistor responsive to a change in voltage of the input signal. The device also comprises means for controlling on and off states of the second transistor based on the floating voltage of the gate of the first transistor. The device also comprises means for transferring the input signal to a drain of the first transistor.

In yet other aspects, a system comprises a first transistor having a source configured to receive an input signal and a drain configured to provide an output signal. In some embodiments, the system also comprises a second transistor connected as a diode and having a source connected to a gate of the first transistor. In other embodiments, the system also comprises a second transistor connected as a diode and having a drain connected to a gate of the first transistor.

In further aspects, a switch comprises a signal path comprising means for selectively passing a signal between an input and an output, and means for biasing the means for selectively passing the signal. In some embodiments, the means for biasing comprises means for providing a high impedance to inhibit voltage discharge from the means for selectively passing the signal. In some embodiments, the means for biasing comprises means for charging the means for selectively passing the signal.

The foregoing is a summary and thus contains, by necessity, simplifications, generalizations and omissions of detail; consequently, those skilled in the art will appreciate that the summary is illustrative only and does not purport to be limiting in any way. Other aspects, inventive features, and advantages of the devices and/or processes described herein, as defined solely by the claims, will become apparent in the non-limiting detailed description set forth herein.

### BRIEF DESCRIPTION OF DRAWINGS

The detailed description references the accompanying figures. In the figures, the left-most digit(s) of a reference number identifies the figure in which the reference number first appears. The use of the same reference numbers in different instances in the description and the figures may indicate similar or identical items.

FIG. 1 illustrates an example operating environment in accordance with one or more aspects of the disclosure.

FIG. 2A illustrates example switch circuitry in accordance with one or more aspects of the disclosure.

FIG. 2B illustrates example switch circuitry in accordance with one or more aspects of the disclosure.

FIG. 3 illustrates an example use of switch circuitry in accordance with one or more aspects of the disclosure.

FIG. 4A illustrates an example method for configuring and operating a transistor switch in accordance with one or more aspects of the disclosure.

FIG. 4B illustrates an example method for configuring and operating a transistor switch in accordance with one or more aspects of the disclosure.

FIG. 5 illustrates an example device having components through which aspects of configuring and operating a transistor switch can be implemented in accordance with one or more aspects of the disclosure.

### DETAILED DESCRIPTION

Switches are used ubiquitously throughout communications and computing devices. Transistors are configured as switches and implemented in semiconductor devices to route data and select appropriate signals among a plurality of signals (e.g., such as in a multiplexor). For instance, transistor switches are often used to separate transmitting and receiving radio frequency (RF) signals that may share an antenna in a cellular phone because of the speed and performance of a transistor switch. However, transistor switches with a fixed voltage on the gate of the transistor can suffer degradations in performance, including linearity and insertion loss, when the input voltage swing is high. For example, when the switch is in an on state (e.g., the switch is “closed” or enabled), large voltage swings in the input signal cause an increase in non-linear distortion terms measured on the output signal of the switch, such as the third-order intercept point of harmonics of the input signal.

One method of setting the gate voltage on a transistor configured as a switch is to use a charge pump circuit. Charge pump circuits, however, may be expensive, in terms of area, power, and complexity. Furthermore, charge pump circuits may require a clock signal to operate. In addition, charge pump circuits may maintain a fixed gate voltage of the transistor, rather than allowing the gate voltage to float. Accordingly, because the gate voltage is fixed, when the input signal on the source of the transistor contains large voltage swings, the gate to source voltage of the transistor is reduced, causing nonlinear distortion measurable on the output of the switch at the transistor drain.

Another method of setting the gate voltage on a transistor configured as a switch is to use a resistor connected to the gate of the transistor and a control voltage. Using such a resistor allows the gate voltage of the transistor to float (e.g., increase or decrease in proportion to voltage increases and decreases of the input signal applied to the source of the transistor). Though simple to implement in many embodiments, the size of the resistor (e.g., the required resistance value of the resistor) scales inversely proportionally to the frequency of the input signal. Hence, what might be implementable for a switch processing RF signals may be prohibitive for a switch in a baseband environment due to the required size of the resistor. For example, the inventors have determined that to use a resistor to float a gate voltage of a transistor configured as a switch in a baseband environment would require approximately 500 Mega-ohms to achieve acceptable linearity performance for certain configurations, and approximately 10 Giga-ohms to match the linearity performance of certain techniques described herein. Such linearity performance may be measured using the third-order intercept point at the output of the switch when the input is a tone (e.g., based on the power of a tone at the output that is three times the frequency of the input tone). Resistors of this size currently are generally impractical for implementation on a chip.

In contrast to using a charge pump circuit or a resistor to bias the gate voltage of a transistor configured as a switch, certain embodiments herein use a diode-connected transistor (e.g., the transistor's gate is connected to its drain for an NMOS transistor) to bias a floating gate voltage on a transistor configured as a switch. The diode-connected transistor is automatically enabled and disabled (e.g., turned on and off) responsive to voltage changes in the input signal. Thus, when the diode-connected transistor is enabled, it charges the gate of the transistor configured as a switch to a sufficiently high voltage to enable the transistor switch (e.g., turn it on), and when the diode-connected transistor is disabled, it acts as a high impedance to inhibit voltage discharge from the gate of the transistor switch so that it stays enabled. Therefore, the diode-connected transistor and the transistor configured as a switch act in a self-biasing scheme to ensure the transistor configured as a switch is fully enabled and operating in a linear mode where nonlinear distortion terms are reduced.

In the following discussion, an example system including a bias circuit and transistor configured as a switch is described. Techniques that elements of the example system may implement, and a device on which elements of the example system may be embodied, are also described. Consequently, performance of the example procedures is not limited to the example system and the example system is not limited to performance of the example procedures. Any reference made with respect to the example system, or elements thereof, is by way of example only and is not intended to limit any of the aspects described herein.

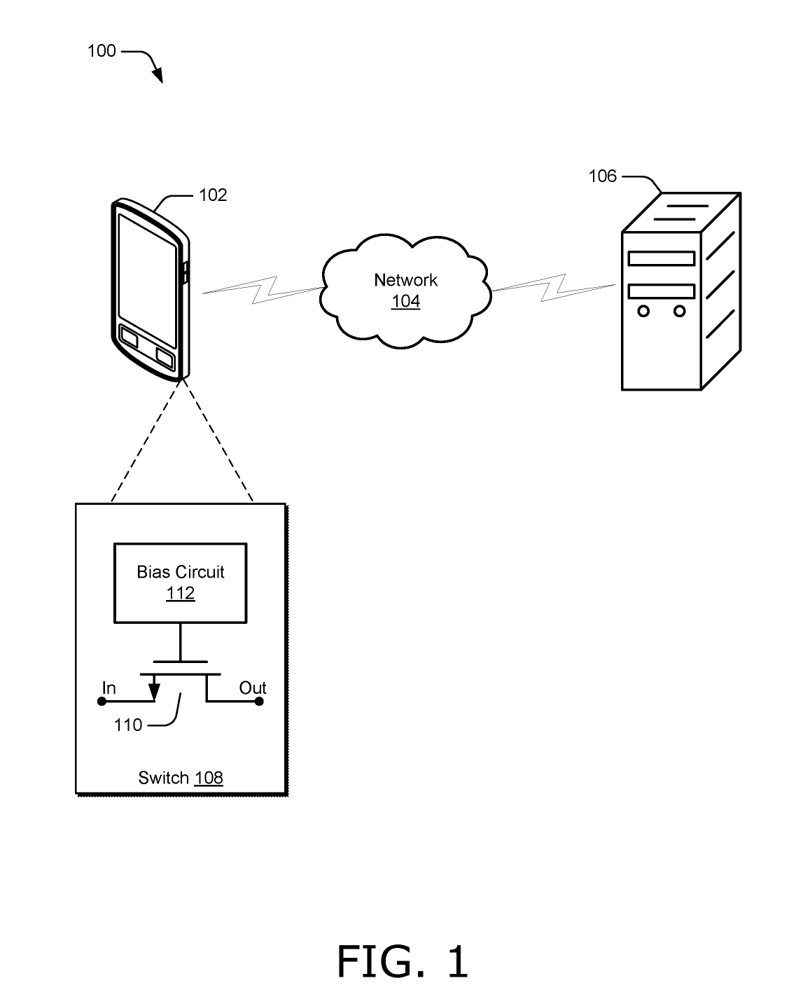

FIG. 1 illustrates example operating environment 100 in accordance with one or more aspects of the disclosure. Example environment 100 comprises user device 102 communicating via network 104 with computing device 106. User device 102 can be any suitable type of computing device, such as a client device, a desktop computer, a laptop computer, a mobile device (e.g., assuming a handheld configuration such as a tablet or mobile phone), a tablet, a camera, a gaming device, a set-top box, a satellite receiver, a cable television receiver, an access point, a vehicle navigation system, and the like. Thus, user device 102 may range from full resource devices with substantial memory and processor resources (e.g., personal computers, game consoles) to a low-resource device with limited memory and/or processing resources (e.g., internet of things (IoT) device). Additionally, although a single user device 102 is shown, the user device 102 may be representative of a plurality of different devices to perform operations “over the cloud”.

Though illustrated as coupled to network 104 in FIG. 1, user device 102 can also operate stand-alone, e.g., while not connected to a network. For example, a user may disconnect user device 102 from network 104 by any suitable fashion, such as selection of an option in a user interface to disable transceiver operation in user device 102, and place user device 102 in an “airplane mode”.

Network 104 may comprise a variety of networks, including the Internet, an intranet, local area network (LAN), wide area network (WAN), personal area network (PAN), body area network (BAN), cellular networks, terrestrial networks, satellite networks, combinations of networks, and the like, and as such may be wired and/or wireless.

Computing device 106 is a device that is communicatively coupled via network 104 to user device 102. In one example, computing device 106 is a server configured to provide data and services to user device 102 responsive to receiving a request from user device 102. Some examples of services include, but are not limited to, a photo editing and storage service, a web development and management service, a collaboration service, a social networking service, a messaging service, an advertisement service, and so forth. In another example, computing device 106 is a client device, and computing device 106 and user device 102 communicate in a peer-to-peer (P2P) fashion.

User device 102 contains one or more switches, an example of which is switch 108, comprising transistor 110 and bias circuit 112. Transistor 110 is configured as a switch, and receives an input signal on a source of transistor 110, and supplies an output signal on a drain of transistor 110, responsive to setting a bias voltage on a gate of transistor 110 from bias circuit 112. For example, bias circuit 112 sets the voltage on the gate of transistor 110 sufficiently large to cause the input signal on the source of transistor 110 to be transferred to the drain of transistor 110. A sufficiently large voltage may be V_{DD}-V_{TH}, where V_{DD} is a positive supply voltage, such as 1.8 volts, and V_{TH} is a minimum gate-to-source voltage needed to create a conducting path between source and drain, whose value depends on the physical implementation of the transistor (e.g., a few tenths of a volt). In this case, transistor 110 is said to be enabled, (e.g., corresponding to an on state). Conversely, bias circuit 112 sets the voltage on the gate of transistor 110 sufficiently small to inhibit the input signal on the source of transistor 110 from being transferred to the drain of transistor 110. A sufficiently small voltage may be a negative voltage, such as the negative of V_{DD}, e.g., −1.8 volts. In this case, transistor 110 is said to be disabled, (e.g., corresponding to an off state).

Transistor 110 is illustrated as an n-channel metal-oxide-semiconductor field-effect transistor (MOSFET) operating in enhancement mode. Though transistor 110 is illustrated as an n-channel MOSFET, transistor 110 can be any suitable type of transistor, such as a junction field-effect transistor (JFET), metal-semiconductor field-effect transistor (MESFET), bipolar junction transistor (BJT), and the like, and operate in any suitable type of mode, such as depletion mode or enhancement mode. Furthermore, transistor 110 can be n-channel or p-channel, and is illustrated as re-channel for convenience.

Switch 108 in FIG. 1 is illustrated as a single switch. In implementations, switch 108 comprises a plurality of transistors and bias circuits, each similar to transistor 110 and bias circuit 112, respectively, and therefore represents a plurality of switches configured in any suitable fashion. Further, a switch 108 can represent a plurality of switches configured to comprise a multiplexor or demultiplexor, capable of providing parallel-to-serial conversion, or serial-to-parallel conversion, respectively. In addition, switch 108 is illustrated as being a part of user device 102 for simplicity, and can be incorporated in any suitable device, such as user device 102, components of network 104, and/or computing device 106. In implementations, switch 108 can be a part of a stand-alone device that is not connected to a network, such as user device 102 when it is disconnected from network 104.

Switch 108 can be used to facilitate numerous functions in user device 102. By way of example and not limitation, switch 108 is an RF transmit/receive switch for selecting transmitting and receiving signals that share an antenna in user device 102, such as a transmit signal to be transmitted by a transmitter, or a received signal to be received by a receiver. In another example, switch 108 is used to construct a multiplexor or demultiplexor and route sub-channel data in a multiple-input and multiple-output transceiver used to communicate orthogonal frequency division multiplexed (OFDM) signals. In still another example, switch 108 is used to select between outputs of filter stages in a multi-stage filter, such as a multi-stage filter that processes baseband signals in a transceiver of a cellular phone. Therefore, example environment 100 is illustrative of example implementations of switch 108 and does not purport to be limiting in any way.

Having considered a discussion of example environment 100, consider now a discussion of example switch circuitry.

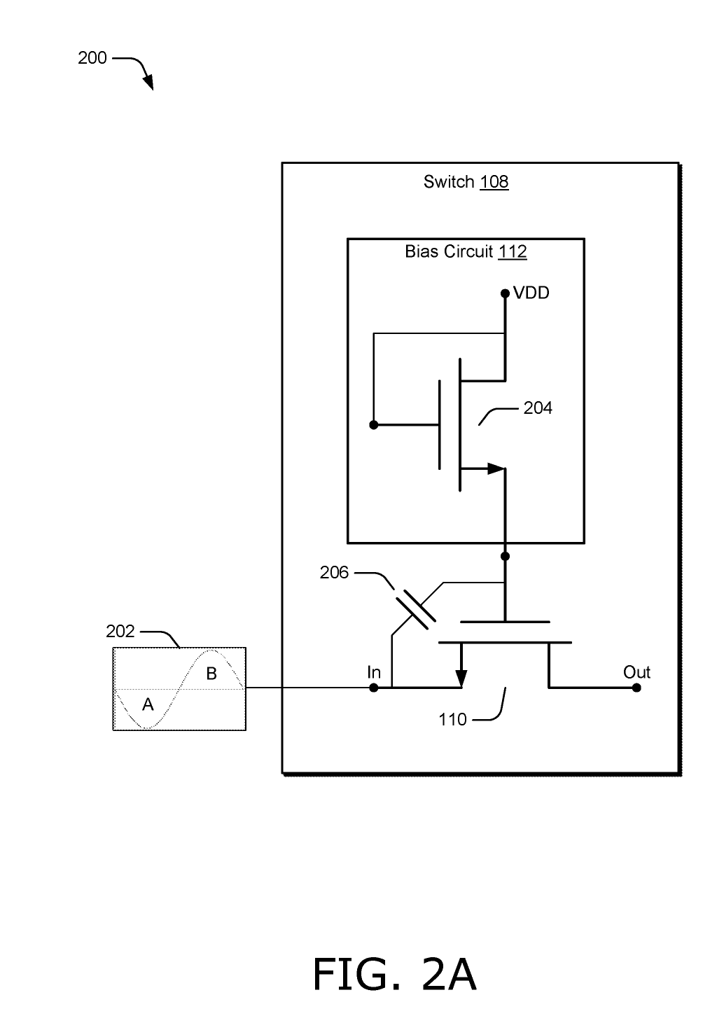

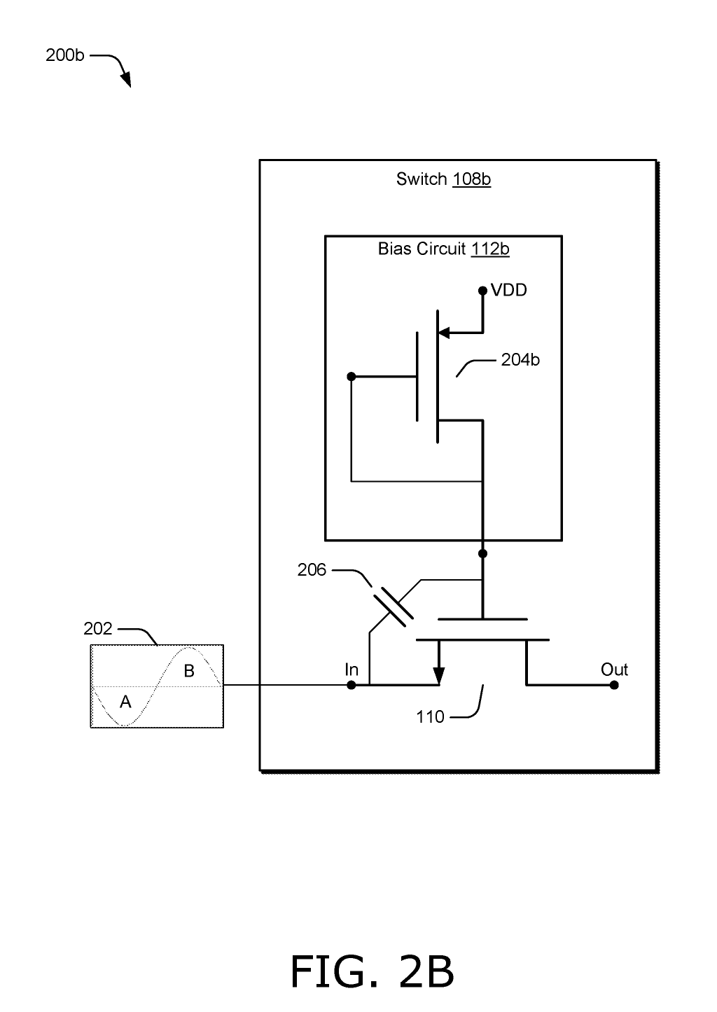

FIG. 2A illustrates example switch circuitry 200 in accordance with one or more aspects of the disclosure. Switch circuitry 200 comprises switch 108 that is configured to receive an input signal 202. Switch 108 includes a transistor 110 and a bias circuit 112, which includes diode-connected transistor 204 that is configured for setting a voltage on the gate of transistor 110. The gate voltage of transistor 110 is not fixed, and is instead allowed to float by tracking voltage variations in input signal 202. Switch 108 has a parasitic capacitance due to the construction of transistor 110, which is illustrated in FIG. 2A as capacitor 206 connected between the gate and the source of transistor 110. In some embodiments, the switch 108 includes a diode of another form in place of the transistor 204. In FIG. 2A, the transistor 204 and the transistor 110 are illustrated as N-channel or NMOS transistors. In other embodiments, one or both of the transistors 204 and 110 may be implemented as a P-channel or PMOS transistors. For example, as illustrated in FIG. 2B, switch circuitry 200b may include a switch 108b having bias circuit 112b. In this embodiment, the bias circuit 112b includes a PMOS diode-connected transistor 204b. As illustrated in FIG. 2B, the source of the transistor 204b is coupled to a supply voltage, and the gate and drain of the transistor 20b is coupled to the gate of the transistor 110.

Returning to the description of FIG. 2A, transistor 110 is configured as a switch, and accepts an input on its source terminal, and supplies an output on its drain terminal. When transistor 110 is enabled (e.g., configured to be turned on), an input signal on the source of transistor 110 is transferred to the drain of transistor 110. Conversely, when transistor 110 is disabled (e.g., configured to be turned off), an input signal on the source of transistor 110 is inhibited from being transferred to the drain of transistor 110. Transistor 110 can be enabled and disabled by setting an appropriate voltage on the gate of transistor 110, which is done by setting the drain of transistor 204 to an appropriate voltage in bias circuit 112. For instance, the drain of transistor 204 is illustrated in FIG. 2A as set to V_{DD} (a positive supply voltage), such as+1.8 volts, to enable transistor 110. Conversely, setting the drain of transistor 204 to a sufficiently low or negative voltage, such as−1.8 volts, would disable transistor 110.

Bias circuit 112 includes diode-connected transistor 204. Transistor 204 is connected as a diode by connecting the gate of transistor 204 to the drain of transistor 204. The drain and gate of transistor 204 are also connected to positive supply voltage V_{DD} to enable transistor 110 (e.g., the switch is closed). The source of diode-connected transistor 204 is connected to the gate of transistor 110 to set a voltage on the gate of transistor 110. Diode-connected transistor 204 is automatically enabled and disabled, e.g., turned on and off, respectively, responsive to voltage swings in input signal 202 that correspondingly cause voltage swings in the floating gate voltage of transistor 110. When diode-connected transistor 204 is enabled, it charges the gate of transistor 110. When diode-connected transistor 204 is disabled, it appears as a high impedance that inhibits voltage discharge from the gate of transistor 110. Therefore, diode-connected transistor 204 acts to keep transistor 110 fully on; this may assist with linearity performance. This operation is next described with regards to input signal 202 in FIG. 2A.

Input signal 202 is illustrated as containing one cycle of a sinusoid, broken into region A where the sinusoid swings negative, or decreases, and region B where the sinusoid swings positive, or increases. This representation of input signal 202 is for simplicity, and is not meant to be limiting in any way. Rather, input signal 202 can represent any suitable waveform and is not restricted to the illustrated sinusoid in FIG. 2A. Furthermore, input signal 202 can represent an analog signal or a digital signal, time-domain or frequency-domain data, a baseband signal or RF signal, and the like.

In a first phase corresponding to region A of input signal 202, the sinusoid decreases by swinging low. Since the gate voltage of transistor 110 floats, the gate voltage of transistor 110 follows the voltage swing of the input signal and swings low an amount proportional to the voltage swing of the input signal. The voltage on the source of diode-connected transistor 204 is equal to the voltage on the gate of transistor 110, since the source of diode-connected transistor 204 is connected to the gate of transistor 110. Consequently, once the voltage on the gate of transistor 110 goes below V_{DD}-V_{TH}, diode-connected transistor 204 is enabled (e.g., turned on). When enabled, diode-connected transistor 204 charges the gate of transistor 110 to approximately V_{DD}-V_{TH}. Therefore, the voltage difference between the gate and source, V_{GS}, of transistor 110 is kept large during this first phase, which improves linearity performance of transistor 110. For example, harmonic and intermodulation distortion are reduced by maintaining a large V_{GS} for transistor 110.

In a second phase corresponding to region B of input signal 202, the sinusoid increases by swinging high. Since the gate voltage of transistor 110 floats, the gate voltage of transistor 110 follows the voltage swing of the input signal and swings high an amount proportional to the voltage swing of the input signal. Consequently, once the voltage on the gate of transistor 110 increases an amount to sufficiently decrease V_{GS} of transistor 204, diode-connected transistor 204 is disabled (e.g., turned off). For example, since the gate of diode-connected transistor is connected to VDD, once the gate voltage of transistor 110 swings sufficiently above V_{DD}-V_{TH}, diode-connected transistor 204 will be disabled. When disabled, diode-connected transistor 204 appears as a very high impedance, for example Giga-ohms or other high impedance, to transistor 110. Diode-connected transistor 204, when disabled, therefore inhibits voltage discharge from the gate of transistor 110 by inhibiting charge from bleeding from the gate of transistor 110 because of its high impedance. Moreover, parasitic capacitance 206 acts to keep V_{GS} of transistor 110 approximately constant during this second phase. Thus, during this second phase, V_{GS} of transistor 110 is kept large, so that transistor 110 is fully enabled; this may assist with maintaining linearity performance of switch 108.

Accordingly, diode-connected transistor 204 is configured to be automatically enabled and disabled responsive to changes in voltage of input signal 202. For example, diode-connected transistor 204 is configured to automatically turn on responsive to decreases in voltage of the input signal, and automatically turn off responsive to increases in voltage of the input signal. Moreover, because the gate voltage of transistor 110 is a floating voltage that tracks the input signal applied to the source of transistor 110, on and off states of diode-connected transistor 204 are controlled based on the floating voltage of the gate of transistor 110, automatically and without user intervention. When enabled, diode-connected transistor 204 charges the gate of switch transistor 110, and when disabled, diode-connected transistor 204 inhibits voltage discharge from the gate of switch transistor 110 by acting as a very high impedance.

Furthermore, unlike using a charge pump circuit that requires a clock signal to operate, diode-connected transistor 204 does not require a clock signal to operate. Hence, switch 108 is self-biasing, responsive to variations in the input signal. Diode-connected transistor 204 ensures transistor 110 is fully enabled with a large V_{GS} when in an on state (e.g., the switch is closed); this may result in increased linearity performance, even in the presence of large voltage swings on the input signal.

Diode-connected transistor 204 is illustrated as an n-channel MOSFET operating in enhancement mode in FIG. 2. Diode-connected transistor 204, however, can be any suitable type of transistor, such as a JFET, MESFET, BJT, and the like, and operate in any suitable type of mode, such as depletion mode or enhancement mode.

In embodiments, diode-connected transistor 204 and switch transistor 110 are a same type of transistor, such as n-channel MOSFET's. Moreover, diode-connected transistor 204 and switch transistor 110 can be fabricated in a same process type, including a same process dimension. For example, diode-connected transistor 204 and switch transistor 110 can be part of an application-specific integrated circuit (ASIC), such as a System-on-Chip (SoC).

Having considered a discussion of example switch circuitry 200, consider now a discussion of an example use of switch circuitry.

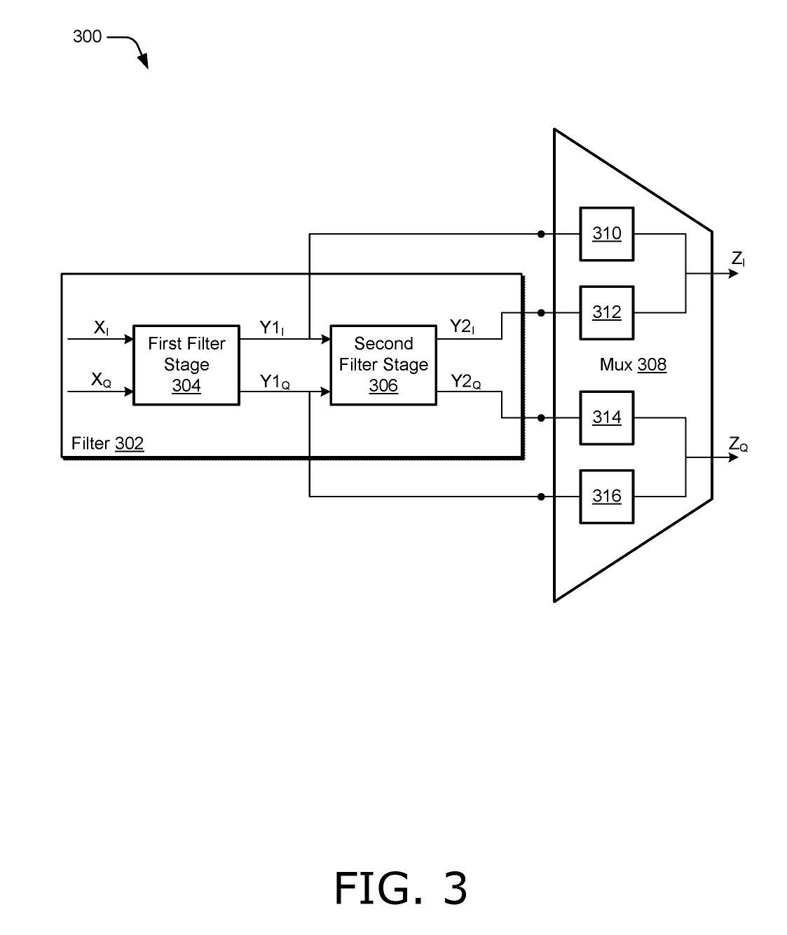

FIG. 3 illustrates an example use of switch circuitry 300 in accordance with one or more aspects of the disclosure. Example use of switch circuitry 300 includes filter 302. Filter 302 is a multi-stage filter that comprises a plurality of filter stages. Outputs of the plurality of filter stages are selectable as outputs of filter 302. This operation may be advantageous when it can be determined that acceptable performance can be achieved using only some of the filter stages. In this case, since only some of the filter stages are needed, other filter stages that are not needed can consequently be disabled to save power. For example, signaling information, including modulation, number of carriers, coding, channel characteristics, and the like, may be known a priori, or estimated, and used to determine an appropriate amount of filter rejection (e.g., attenuation at prescribed frequencies) and select an output of filter 302 corresponding to a filter stage that meets the determined amount of filter rejection.

Filter 302 is illustrated for simplicity as a two-stage filter, including first filter stage 304 and second filter stage 306. Filter 302 is not limited to two stages, and can be any suitable number of filter stages, for example based on the types of signals processed by filter 302 and requirements placed on filter 302. Furthermore, filter 302 and its filter stages, such as filter stage 304 and 306, can be any suitable type of filter structure, such as a linear, transversal filter, a filter with an infinite impulse response, a time-domain filter, a frequency-domain filter, a lattice filter, an analog filter, a digital filter, adaptive filter, combinations thereof, and the like. Moreover, filter 302 is illustrated as processing complex-valued inputs and producing complex-valued outputs, though filter 302 is not so limited. For example, filter 302 can contain real-valued or complex-valued coefficients, and can process real-valued or complex-valued inputs to produce real-valued or complex-valued outputs, including combinations thereof.

In one example, a complex-valued input can represent in-phase and quadrature-phase components of a communication signal processed by filter 302. Using this example, complex-valued input is represented as comprising in-phase component X_{I} and quadrature-phase component X_{Q}, and is supplied to first filter stage 304 in FIG. 3. An output of first filter stage 304, represented as comprising in-phase component Y1_{I} and quadrature-phase component Y1_{Q}, is supplied as input to second filter stage 306, which produces output represented as comprising in-phase component Y2₁ and quadrature-phase component Y2_{Q}.

Example use of switch circuitry 300 also includes multiplexor 308. Outputs of each of first filter stage 304 and second filter stage 306 are supplied as inputs to multiplexor 308. Multiplexor 308 comprises a plurality of switches, including switches 310, 312, 314, and 316. Each of switches 310, 312, 314, and 316 may be substantially the same, or similar to switch 108 or 108b in FIGS. 2. Switch 310 receives filter stage output Y1_{I} as input; switch 312 receives filter stage output Y2_{I} as input; switch 314 receives filter stage output Y2_{Q} as input; and switch 316 receives filter stage output Y1_{Q} as input. By enabling one of switches 310 and 312 while disabling the other of switches 310 and 312, and by enabling one of switches 314 and 316 while disabling the other of switches 314 and 316, multiplexor 308 is configurable to select a complex-valued output, represented as comprising in-phase component Z_{I} and quadrature-phase component Z_{Q}, corresponding to the output of a desired filter stage of filter 302. Switches 310, 312, 314, and 316 are enabled and disabled by connecting a diode-connected transistor comprising each of the switches to appropriate voltages, as described previously with regards to FIGS. 2.

Using switches configured similarly to switches 310, 312, 314, and 316, a multiplexor and/or demultiplexor can be constructed to accept any suitable number of inputs and produce any suitable outputs, such as for providing parallel-to-serial conversion, or serial-to-parallel conversion. For example, a multiplexor and/or demultiplexor can be used to route sub-channel data in a multiple-input and multiple-output transceiver used to process OFDM signals. Because switches 310, 312, 314, and 316 are biased using a diode-connected transistor, filter 302 and multiplexor 308 are suitable to process baseband signals (e.g., signals having spectral content much lower than RF) and can be efficiently implemented on a chip, such as an ASIC or SoC.

Having considered a discussion of example use of switch circuitry 300, consider now a discussion of example methods for configuring and operating a transistor switch.

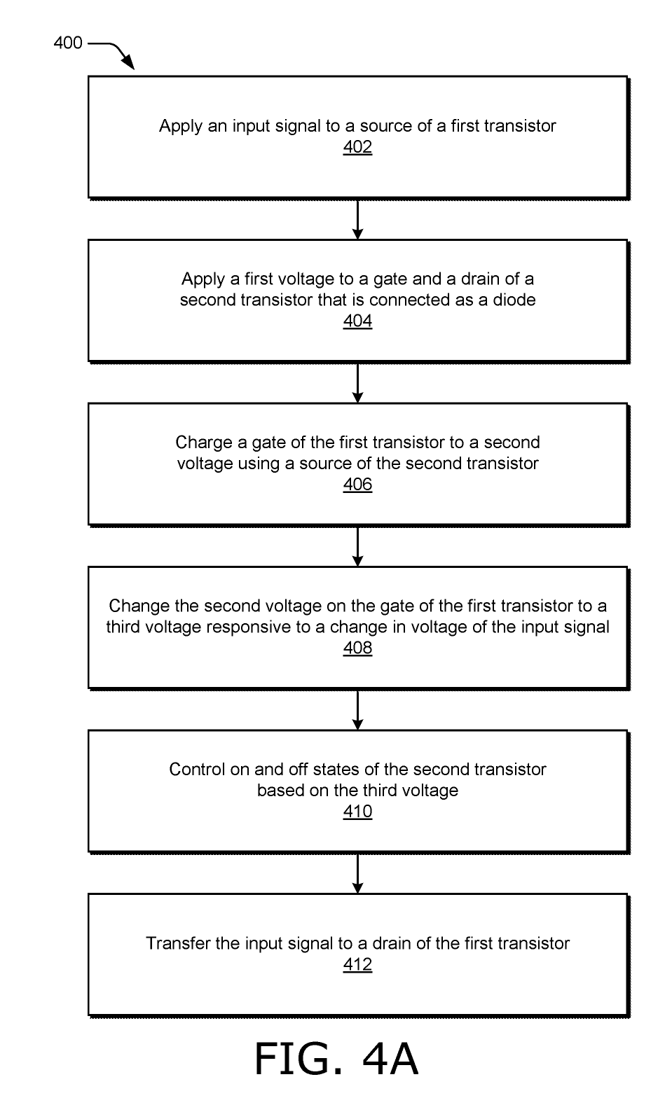

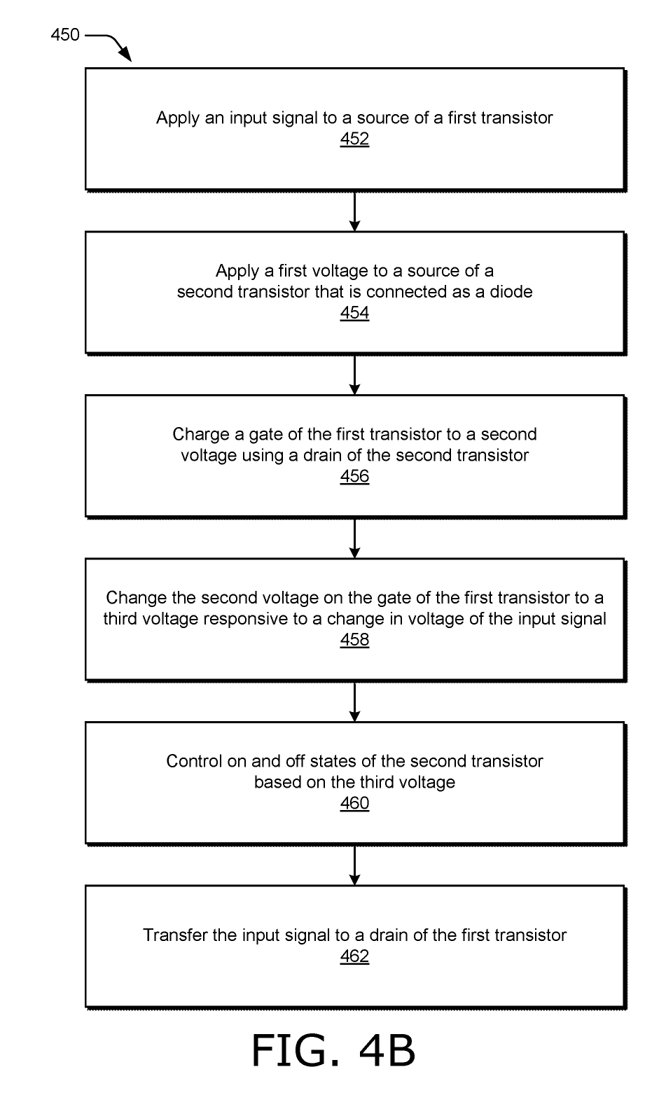

FIG. 4A illustrates an example procedure 400 for configuring and operating a transistor switch in accordance with one or more aspects of the disclosure. Aspects of the procedure may be implemented in hardware, firmware, software, or a combination thereof. The procedure is shown as a set of blocks that specify operations performed by one or more devices and are not necessarily limited to the orders shown for performing the operations by the respective blocks. In at least some embodiments the procedure may be performed by a suitably configured device or devices, such as user device 102 described in FIG. 1.

An input signal is applied to a source of a first transistor (block 402) configured as a switch. For example, the first transistor can be enabled or disabled to transfer or inhibit transfer of, respectively, the input signal to an output terminal of the first transistor, such as a drain of the first transistor.

A first voltage is applied to a gate and a drain of a second transistor that is connected as a diode (block 404). For example, the first voltage can be V_{DD}, a positive supply voltage, such as+1.8 volts. The second transistor is configured as a diode by connecting the drain of the second transistor to the gate of the second transistor. In embodiments, the second transistor operates without a clock signal.

Furthermore, the first transistor at block 402 and the second transistor at block 404 are configured so that a source of the second transistor is connected to a gate of the first transistor. In embodiments, the first transistor at block 402 and the second transistor at block 404 are a same type of transistor. Additionally or alternatively, the first transistor at block 402 and the second transistor at block 404 are manufactured in a same process type.

A gate of the first transistor is charged to a second voltage using a source of the second transistor (block 406). For example, the second transistor, when enabled, charges the voltage on the gate of the first transistor to approximately V_{DD}-V_{TH}, where here V_{TH} is a minimum gate-to-source voltage needed to create a conducting path between source and drain of the second transistor.

The second voltage on the gate of the first transistor is changed to a third voltage responsive to a change in voltage of the input signal (block 408). For instance, the gate of the first transistor is allowed to float in voltage, and tracks voltage swings of the input signal by changing voltage an amount proportional to a voltage change in the input signal. Hence, if the input signal swings high, or increases, the voltage on the gate of the first transistor is changed so that the third voltage is greater than the second voltage. Conversely, if the input signal swings low, or decreases, the voltage on the gate of the first transistor is changed so that the third voltage is less than the second voltage.

On and off states of the second transistor are controlled based on the third voltage (block 410). For example, the second transistor is enabled (e.g., turned on) responsive to a decrease in voltage of the input signal, since the gate voltage of the first transistor floats and tracks the input voltage. When the input signal decreases in voltage, the third voltage decreases so that V_{GS} of the second transistor is consequently increased when the gate of the second transistor is tied to V_{DD}, enabling the second transistor. Similarly, the second transistor is disabled (e.g., turned off) responsive to an increase in voltage of the input signal, which causes the third voltage to increase and V_{GS} of the second transistor to consequently decrease, disabling the second transistor. Therefore, on and off states of the second transistor are controlled automatically and without user intervention, based on a difference between the first voltage and the floating voltage of the gate of the first transistor compared to a threshold voltage V_{TH} of the second transistor.

When the second transistor is configured in the on state (e.g., is enabled), the second transistor charges the gate of the first transistor to a prescribed voltage, such as V_{DD}-V_{TH}. When the second transistor is configured in the off state (e.g., is disabled), the second transistor inhibits voltage discharge from the gate of the first transistor.

The input signal is transferred to a drain of the first transistor (block 412). The drain of the first transistor represents an output terminal of the switch. In embodiments, the first voltage applied to the gate and the drain of the second transistor is decreased, such as to a negative voltage (e.g., the negative value of V_{DD}), in order to disable the switch. In response to decreasing the first voltage, transferring of the input signal to the drain of the first transistor is ceased.

FIG. 4B illustrates an example procedure 450 for configuring and operating a transistor switch in accordance with one or more aspects of the disclosure. Aspects of the procedure may be implemented in hardware, firmware, software, or a combination thereof. The procedure is shown as a set of blocks that specify operations performed by one or more devices and are not necessarily limited to the orders shown for performing the operations by the respective blocks. In at least some embodiments the procedure may be performed by a suitably configured device or devices, such as user device 102 described in FIG. 1.

An input signal is applied to a source of a first transistor (block 452) configured as a switch. For example, the first transistor can be enabled or disabled to transfer or inhibit transfer of, respectively, the input signal to an output terminal of the first transistor, such as a drain of the first transistor.

A first voltage is applied to a source of a second transistor that is connected as a diode (block 454). For example, the second transistor may be configured as a diode by connecting the gate second transistor to the drain of the second transistor. In embodiments, the second transistor operates without a clock signal.

Furthermore, the first transistor at block 452 and the second transistor at block 454 may be configured so that the drain of the second transistor is connected to a gate of the first transistor.

The gate of the first transistor is charged to a second voltage using the drain of the second transistor (block 456). The second voltage on the gate of the first transistor is changed to a third voltage responsive to a change in voltage of the input signal (block 458).

On and off states of the second transistor are controlled based on the third voltage (block 460). The input signal is transferred to a drain of the first transistor (block 462). The drain of the first transistor may represent an output terminal of the switch.

Having considered a discussion of example methods for configuring and operating a transistor switch, consider now a discussion of an example device having components through which aspects of configuring and operating a transistor switch can be implemented.

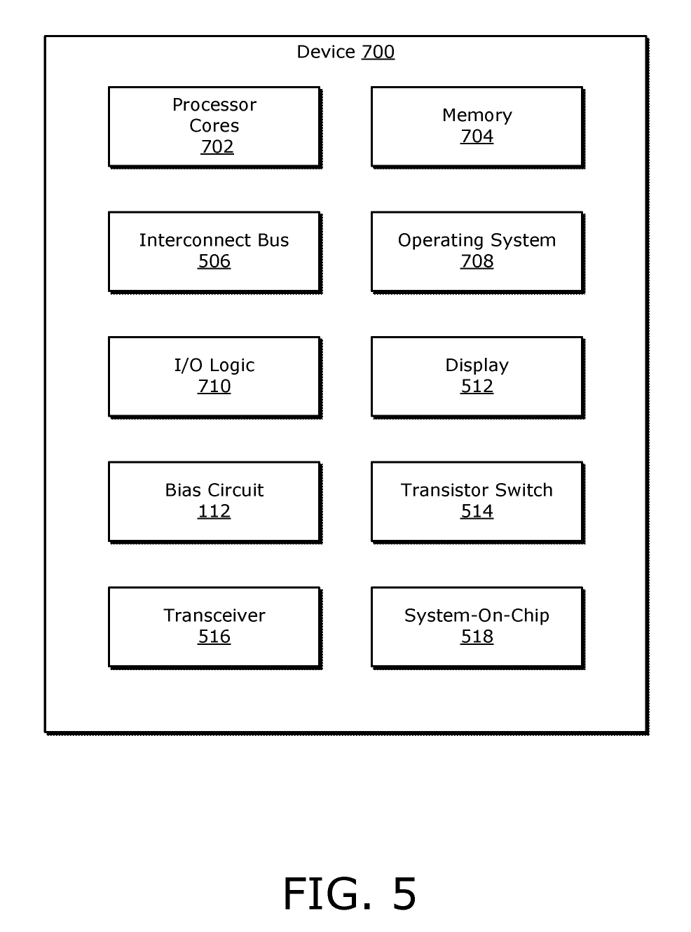

FIG. 5 illustrates an example device 500, which includes components capable of implementing aspects of configuring and operating a transistor switch. Device 500 may be implemented as, or in, any suitable electronic device, such as a modem, broadband router, access point, cellular phone, smart-phone, gaming device, laptop computer, desktop computer, net book, set-top-box, smart-phone, network-attached storage (NAS) device, cell tower, satellite, cable head-end, and/or any other device that may use a transistor switch.

Device 500 may be integrated with a microprocessor, storage media, I/O logic, data interfaces, logic gates, a transmitter, a receiver, circuitry, firmware, software, and/or combinations thereof to provide communicative or processing functionalities. Device 500 may include a data bus (e.g., cross bar or interconnect fabric) enabling communication between the various components of the device. In some aspects, components of device 500 may interact via the data bus to implement aspects of configuring and operating a transistor switch.

In this particular example, device 500 includes processor cores 502 and memory 504. Memory 504 may include any suitable type of memory, such as volatile memory (e.g., DRAM), non-volatile memory (e.g., flash), cache, and the like. In the context of this disclosure, memory 504 is implemented as a storage medium, and does not include transitory propagating signals or carrier waves. Memory 504 can store data and processor-executable instructions of device 500, such as operating system 508 and other applications. Processor cores 502 may execute operating system 508 and other applications from memory 504 to implement functions of device 500, the data of which may be stored to memory 504 for future access. For example, processor cores may switch control signals to configure switches as enabled or disabled. Device 500 may also include I/O logic 510, which can be configured to provide a variety of I/O ports or data interfaces for communication. Device 500 also includes display 512. Display 512 may comprise any suitable type of display, such as a liquid crystal display (LCD), and be configured to provide a user interface on device 500.

Device 500 also includes bias circuit 112. Bias circuit 112 contains at least one diode-connected transistor, such as transistor 204 or 204b in FIGS. 2A, 2B. Furthermore, the diode-connected transistor is connected to a gate of a transistor configured as a switch, such as transistor switch 514 (or 110 in FIGS. 1 and 2). Transistor switch 514 comprises one or more transistors configured as switches. The transistors can be any suitable type of transistors, such as by way of example and not limitation, MOSFET's. Transistor 110 in FIGS. 1 and 2 is an example of a transistor configured as a switch.

Device 500 also includes transceiver 516. Transceiver 516 is any suitable type of transceiver, such as a receiver, transmitter, or combinations thereof, and is configurable for communication of one or more types of signals, such as cellular phone signals. Transceiver 516 can use switches from transistor switch 514 that are controlled using bias circuit 112, such as to route multi-carrier sub-channel data appropriately.

Device 500 also includes System-on-Chip (SoC) 518. SoC 518 comprises a variety of functions on a single chip or die, or multiple die in a single package. In embodiments, SoC comprises bias circuit 112 and transistor switch 514.

In one or more exemplary embodiments, the functions described may be implemented in hardware, software, firmware, or any combination thereof. If implemented in software, functions may be stored on a computer-readable storage medium (CRM). In the context of this disclosure, a computer-readable storage medium may be any available medium that can be accessed by a general-purpose or special-purpose computer that does not include transitory propagating signals or carrier waves. By way of example, and not limitation, such media can comprise RAM, ROM, EEPROM, CD-ROM or other optical disk storage, magnetic disk storage, or other magnetic storage devices, or any other non-transitory medium that can be used to carry or store information that can be accessed by a general-purpose or special-purpose computer, or a general-purpose or special-purpose processor. The information can include any suitable type of data, such as computer-readable instructions, sampled signal values, data structures, program components, or other data. These examples, and any combination of storage media and/or memory devices, are intended to fit within the scope of non-transitory computer-readable media. Disk and disc, as used herein, includes compact disc (CD), laser disc, optical disc, digital versatile disc (DVD), floppy disk and Blu-ray disc where disks usually reproduce data magnetically, while discs reproduce data optically with a laser. Combinations of the above should also be included within the scope of computer-readable media.

Firmware components include electronic components with programmable memory configured to store executable instructions that direct the electronic component how to operate. In some cases, the executable instructions stored on the electronic component are permanent, while in other cases, the executable instructions can be updated and/or altered. At times, firmware components can be used in combination with hardware components and/or software components.

The term “component”, “module”, and “system” are indented to refer to one or more computer related entities, such as hardware, firmware, software, or any combination thereof, as further described above. At times, a component may refer to a process and/or thread of execution that is defined by processor-executable instructions. Alternately or additionally, a component may refer to various electronic and/or hardware entities.

Certain specific embodiments are described above for instructional purposes. The teachings of this disclosure have general applicability, however, and are not limited to the specific embodiments described above.

What is claimed is:

1. A switch comprising:
a first transistor having a source connected to an input of the switch and a drain connected to an output of the switch, the input of the switch being configured to receive an input signal; and
a second transistor connected as a diode and having a source or drain connected to a gate of the first transistor.

2. The switch as recited in claim 1, wherein the second transistor comprises an NMOS transistor and wherein the source of the second transistor is coupled to the gate of the first transistor.

3. The switch as recited in claim 2, wherein a gate of the second transistor is connected to the drain of the second transistor, and the gate and the drain of the second transistor is coupled to a supply voltage.

4. The switch as recited in claim 3, wherein the switch is enabled when the supply voltage is set to a prescribed voltage, and the switch is disabled when the supply voltage is set to a voltage below the prescribed voltage.

5. The switch as recited in claim 1, wherein the second transistor comprises a PMOS transistor and wherein the drain of the second transistor is coupled to the gate of the first transistor.

6. The switch as recited in claim 5, wherein a gate of the second transistor is connected to the drain of the second transistor, and wherein the source of the second transistor is coupled to a supply voltage.

7. The switch as recited in claim 1, wherein the first transistor and the second transistor are a same type of transistor.

8. The switch as recited in claim 1, wherein the gate of the first transistor is configured to float in voltage.

9. The switch as recited in claim 1, wherein the drain of the first transistor is configured to provide an output signal, and wherein the output signal is based on the input signal when a same voltage above a threshold voltage is applied to a gate and the drain of the second transistor.

10. The switch as recited in claim 1, wherein the second transistor is automatically enabled and disabled responsive to voltage swings in the input signal.

11. The switch as recited in claim 1, wherein a voltage on the gate of the first transistor is configured to float responsive to voltage variations in the input signal, and the second transistor is enabled and disabled responsive to the floating voltage on the gate of the first transistor.

12. The switch as recited in claim 1, wherein the second transistor, when turned on, is configured to charge the gate of the first transistor to a voltage.

13. The switch as recited in claim 1, wherein the second transistor when turned off acts as a high impedance to inhibit voltage discharge from the gate of the first transistor.

14. The switch as recited in claim 1, wherein the input signal comprises a baseband communication signal.

15. The switch as recited in claim 1, wherein the switch comprises a transmit/receive switch, and the input of the switch is used to select a transmit signal to be transmitted by a transmitter, or a received signal to be received by a receiver.

16. The switch as recited in claim 1, wherein the switch is included in a multiplexor configured to route sub-channel data in a multiple-input and multiple-output transceiver.

17. The switch as recited in claim 1, wherein the switch is included in a multiplexor configured to select between outputs of filter stages in a multi-stage filter.

18. A method of operating a switch, the method comprising:
applying an input signal to a source of a first transistor;
applying a first voltage to a gate and a drain of a second transistor that is connected as a diode;
charging a gate of the first transistor to a second voltage using a source of the second transistor;
changing the second voltage on the gate of the first transistor to a third voltage responsive to a change in voltage of the input signal;
controlling on and off states of the second transistor based on the third voltage; and
transferring the input signal to a drain of the first transistor.

19. The method as recited in claim 18, wherein the change in voltage of the input signal is an increase in voltage, the third voltage is greater than the second voltage, and the controlling on and off states comprises turning off the second transistor.

20. The method as recited in claim 18, wherein the off state of the second transistor configures the second transistor to act as a high impedance to inhibit voltage discharge from the gate of the first transistor.

21. The method as recited in claim 18, wherein the on state of the second transistor configures the second transistor to charge the gate of the first transistor to the second voltage.

22. The method as recited in claim 18, further comprising:
decreasing the first voltage; and
ceasing, in response to the decreasing, the transferring the input signal to the drain of the first transistor.

23. The method as recited in claim 18, further comprising operating the second transistor without a clock signal.

24. A method of operating a switch, the method comprising:
applying an input signal to a source of a first transistor;
applying a first voltage to a source of a second transistor, the second transistor comprising a gate and a drain that are connected;
charging a gate of the first transistor to a second voltage using the drain of the second transistor; changing the second voltage on the gate of the first transistor to a third voltage responsive to a change in voltage of the input signal;
controlling on and off states of the second transistor based on the third voltage; and
transferring the input signal to a drain of the first transistor.
